(19) United States
(12) Patent Application Publication
(10) Pub. No.: US 2004/0251044 A1
(43) Pub. Date: Dec. 16, 2004

(54) Ceramic package and fabrication method thereof

(76) Inventors: Ik Seo Choi, Yongin (KR); Seok Taek Jun, Suwon (KR); Yong Wook Kim, Seoul (KR); Jung Sub Choi, Suwon (KR)

Correspondence Address: LOWE HAUPTMAN GOPSTEIN GILMAN & BERNER, LLP, Suite 310, 1700 Diagonal Road, Alexandria, VA, 22314, US

(21) Appl. No.: 10/631,859

(22) Filed: Aug. 1, 2003

(30) Foreign Application Priority Data
Jun. 10, 2003 (KR) 2003-37031

(51) Int. Cl. H01L 23/02

(52) U.S. Cl. 174/52.4

(57) ABSTRACT

The present invention relates to a multilayer ceramic package providing an improved connection pattern structure between inside and outside terminals and a fabrication method thereof. The ceramic package internally mounts at least one component and is formed by stacking a plurality of ceramic sheets one atop another. Internal patterns are formed in at least a portion of the ceramic sheets. A lid is mounted on the layered structure above the cavity to maintain the cavity airtight. Outside connection terminals are formed in outer portions of the layered structure. Internal connection patterns are separately formed horizontally in at least two of the ceramic sheets to be electrically connected with the outside connection terminals. Inside connection terminals formed within the cavity to be electrically connected with the component and at least a portion of the internal connection pattern.

### BACKGROUND OF THE INVENTION

1. Field of the Invention

The present invention relates to a multilayer ceramic package for mounting components in an internal cavity and a fabrication method thereof, and more particularly, a multilayer ceramic package providing an improved connection pattern structure between inside and outside terminals and a fabrication method thereof.

2. Description of the Related Art

Low Temperature Co-fired Ceramic (LTCC) technology primarily prepares passive elements (R, L and C) embodying given circuits on a plurality of green sheets, which are made mainly based upon glass ceramic, via screen printing with metal excellent in electric conductivity such as silver (Ag) and copper (Cu), stacks the green sheets one atop on another, and then co-fires ceramics and metal conductors (at a temperature of about 100° C. or less) in order to fabricate Multi-Chip Modules (MCMs) and Multi-Chip Packages.

LTCC technology advantageously realizes the passive elements (R, L, C) within a module on account of process characteristics, which enable co-firing of ceramic and metal, so that composite components or modules can be obtained with reduced sizes.

An LTCC substrate based upon its characteristics of realizing embedded passives can embody a System-On-a-Package (SOP) to minimize parasitic effects which are created from Surface Mounted Devices (SMD). There are also advantages that electric characteristics are improved through reduction of electric noise signals which are created from soldered regions in surface mounting, and reliability is improved through decrease in the number of solders. The LTCC substrate can also minimize Temperature Coefficient of Resonant Frequency (Tf) through control of thermal expansion coefficient so as to adjust characteristics of a dielectric resonator.

The LTCC substrate can mount active elements such as a Surface Acoustic Wave (SAW) filter and power Amplifier Module (PAM) to realize a multifunctional module. In particular, the SAW filter can be mounted on the LTCC substrate by forming a cavity in the LTCC substrate for housing SAW filter chips, or by mounting SAW filter chips on the outer surface of the LTCC substrate.

Mounting the SAW filter chips within the cavity can advantageously reduce the size of devices as well as save material costs, and thus is being classified as a advantageous design policy for reducing the size of devices and saving material costs. In a package which houses components in a cavity of an LTCC substrate, however, if the components mounted in the cavity require at least a predetermined level of airtightness, it is necessary to maintain the LTCC substrate to the required level of airtightness to protect the internal components from external environments thereby ensuring normal operation to the components.

In particular, where the mounting cavity requires at least a predetermined level of airtightness as in an SAW filter, it has been troublesome to maintain the required level of airtightness to the LTCC package.

FIG. 1 is a sectional view of a conventional ceramic package having components internally housed therein.

Referring to FIG. 1, the ceramic package comprises multilayer ceramic sheets defining a base layer 11 on which components 12 are mounted and an intermediate layer or cavity layer 10 in which a cavity 19 is formed. The components 12 such as an SAW filter are mounted in the cavity 19 via conductive bonding means 18 and so on. On the top of the cavity layer 10, there is mounted a cover or lid 13 for maintaining the cavity 19 of the package airtight via a bonding layer 14.

Internal connection patterns 15 and 15′ are formed for connecting the components 12 in the cavity 19 with outside terminals 16 (see FIG. 2) so that the components 12 can interchange signals with the outside. The connection patterns 15 and 15′ are connected with the outside terminals through the inside of a ceramic substrate, and continuously exist in specific ones of several ceramic sheets which are stacked one atop another.

Describing in more detail, FIG. 2 is a plan view of the base layer 11 for mounting the components of the ceramic package in FIG. 1. The internal connection pattern 15 is continuously formed in the base layer 11 for connecting the components 12 in the cavity 19 with the outside terminals 16.

FIG. 3 is a plan view of a ground layer functioning as a ground which is connected with the lid 13 placed over the cavity 19. In FIG. 3, the continuous connection pattern 15′ is formed on the cavity layer 10 in order to be connected with outside terminals 16′.

In fabrication of the ceramic package having the connection pattern layers in the ceramic multilayer substrate as shown in FIGS. 2 and 3, the ceramic sheets are bonded together based upon the adhering force between the ceramic sheets, with the connection pattern layers placed among the sheets. That is, the connection patterns are continuously formed in the corresponding layers from inside the cavity to outside the ceramic package, forming paths which cause leak from outside through the outside terminals 16 and 16′ and the connection pattern layers 15 and 15′. The leak paths make it difficult to keep the cavity airtight to at least a predetermined level.

Such a phenomenon that components housed in the cavity of the ceramic multilayer substrate have a lowered degree of vacuum or airtightness is referred to as leak defect. Leak defect is caused by the pattern structure that the internal connection patterns in the ceramic multilayer substrate are extended on common layers from the outside terminals of the substrate into inside the cavity. It is known that propagation paths of leak exist in the patterns of the connection terminals.

Furthermore, excessive pressure applied against the ceramic sheets stacked one atop another for the purpose of closely contacting the ceramic sheets with the connection pattern layers interposed among the sheets tends to worsen the evenness of a bottom on which the components are mounted so that the components may be defectively mounted.

FIG. 4 is a sectional view of another conventional ceramic package having components internally housed therein. Likewise to the ceramic package in FIG. 1, the ceramic package in FIG. 4 comprises a base layer 11 on which components 22 are mounted and an intermediate layer or cavity layer 20 in which a cavity 29 is formed. The components 22 such as an SAW filter are housed in the cavity 29 via conductive bonding means 28. A cover or lid 23 is mounted on the top of the cavity layer 20 over the cavity 29 via bonding means 24 in order to maintain the cavity 29 airtight.

There are formed internal connection patterns 25 for enabling signal interchange between inside terminals 27, which are in contact with the internally mounted components 22, and outside terminals 26, so that the internal components 22 can interchange signals with the outside. The connection patterns 25 are formed by filling conductive material into via holes in ceramic sheets which are stacked one atop another underlying the inside terminals 27.

The ceramic package structure in FIG. 4 is discriminated from that in FIG. 1 in which the outside terminals are formed in lateral portions of the ceramic package and internal connection patterns are horizontally formed. The structure in FIG. 4 removes the laterally connected terminals in order to further improve the airtightness of the cavity.

However, the above structure of connection patterns which vertically connect the inside terminals with the outside terminals causes restrictions to the design flexibility of the circuit patterns for realizing circuit elements on the ceramic multilayer sheets underlying the internal components. That is, there is a drawback that the above package structure is applicable only to simple packages such as an SAW package or a vibrator in which additional patterns are not formed within the package to act as circuit elements.

Furthermore, the via holes which are extended downward to form the internal connection patterns cause design limitations that the via holes with a predetermined diameter must be formed on the ceramic substrate. This results in the difficulty in size reduction of the package.

Therefore, it has been required in the art a fabrication technique of ceramic packages which can solve the above problems.

### SUMMARY OF THE INVENTION

The present invention has been made to solve the foregoing problems of the prior art and it is therefore an object of the present invention to provide a ceramic package which prevents leak paths along which leak occurs from outside in order to eliminating leak defects.

It is another object of the invention to prevent defective mounting of components resulting from degraded evenness of a bottom for mounting the components which may be caused by excessively pressing ceramic sheets for the purpose of preventing leak defects in fabrication of a ceramic package.

It is yet another object of the invention to provide a ceramic package which can improve the design flexibility of patterns for forming circuit elements of ceramic multilayer sheets as well as reduce the size of an article.

According to an aspect of the invention for realizing the object, there is provided a ceramic package for internally mounting at least one component, comprising: a layered structure formed by stacking a plurality of ceramic sheets one atop another, having an internal cavity for housing the component and internal patterns in at least a portion of the ceramic sheets; a lid mounted on the layered structure above the cavity to maintain the cavity airtight; outside connection terminals formed on outer portions of the layered structure; internal connection patterns separately formed horizontally in at least two of the ceramic sheets to be electrically connected with the outside connection terminals; and inside connection terminals formed within the cavity to be electrically connected with the component and at least a portion of the internal connection patterns.

It is preferred that the separate internal connection patterns are electrically connected through via holes. It is also preferred that the internal connection patterns are separately formed in adjacent ones of the ceramic sheets.

It is preferred that the internal connection patterns comprise upper internal connection patterns formed adjacent to the lid and lower internal connection patterns connected with the inside connection terminals. It is more preferred that the lower internal connection patterns comprise a first pattern which is formed on a ceramic sheet as that of the inside connection terminals for electric connection therewith, and a second pattern which is connected with the outside connection terminals and formed in a second ceramic sheet different from that of the first pattern, and that the upper internal connection patterns comprise a first pattern formed on a layer on which the lid is mounted, and a second pattern which is connected with the outside connection terminals and formed on a ceramic sheets different from that of the first pattern.

The ceramic package of the invention may further comprise inside patterns for realizing circuit elements in at least one of the ceramic sheets which underlies the lower internal connection patterns.

According to another aspect of the invention for realizing the object, there is provided a fabrication method of a ceramic package capable of mounting components within a cavity, the method comprising the steps of: preparing a plurality of ceramic sheets; forming pattern layers in at least a portion of the ceramic sheets to realize circuit elements; forming outside connection terminals for signal interchange with the outside and forming inside connection terminals connected with the components in a portion of the ceramic sheets; separately forming internal connection patterns on at least two of the ceramic sheets, for connecting the outside connection terminals with the lid mounted over the cavity or with the inside connection terminals; forming conductive via holes in a portion of the ceramic sheets to electrically connect the separate internal connection patterns which are formed in the ceramic sheets; and stacking the ceramic sheets one atop another.

It is preferred that the internal connection patterns are separately formed in adjacent ones of the ceramic sheets, and that the internal connection patterns comprise upper internal connection patterns formed adjacent to the lid and second internal connection patterns connected with the inside connection terminals.

It is preferred that the lower internal connection patterns comprise a first pattern which is formed on a same ceramic sheet as that of the inside connection terminals for electric connection therewith, and a second pattern which is connected with the outside connection terminals and formed in a second ceramic sheet different from that of the first pattern, and that the upper internal connection patterns comprise a first pattern formed on a layer on which the lid is mounted, and a second pattern which is connected with the outside connection terminals and formed on a ceramic sheet different from that of the first pattern.

It is also preferred that inside patterns for realizing circuit elements are provided in at least one of the ceramic sheets which underlies the lower internal connection patterns.

### BRIEF DESCRIPTION OF THE DRAWINGS

The above and other objects, features and other advantages of the present invention will be more clearly understood from the following detailed description taken in conjunction with the accompanying drawing, in which:

FIG. 1 is a sectional view of a conventional ceramic package having components internally housed therein;

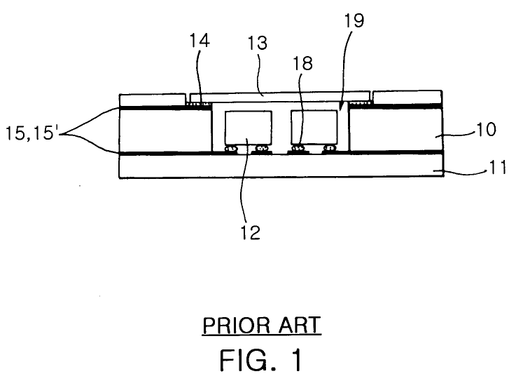

FIG. 2 is a plan view of a base layer of the ceramic package in FIG. 1 on which components are internally mounted;

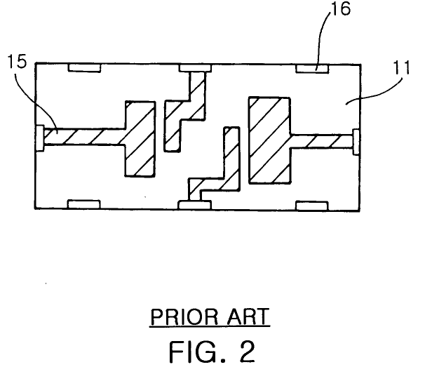

FIG. 3 is a plan view of a ground layer over a cavity in the ceramic package in FIG. 1;

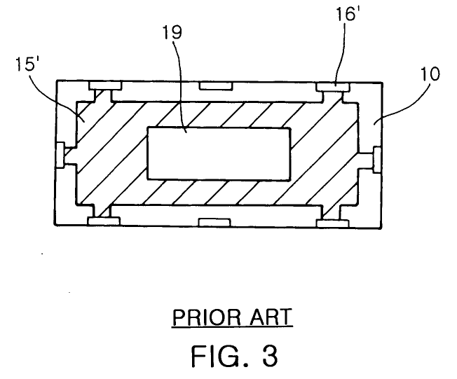

FIG. 4 is a sectional view of another conventional ceramic package having components internally housed therein;

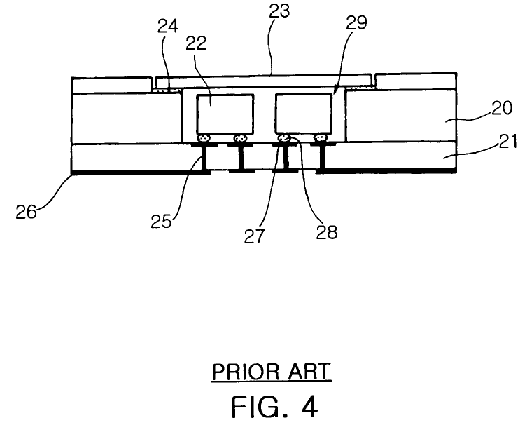

FIG. 5 is a sectional view of a ceramic package of the invention;

FIG. 6 is a magnification of a part A in FIG. 5;

FIG. 7A is a plan view of abase layer of the ceramic package in FIG. 5 on which components are internally mounted;

FIG. 7B is a plan view of a sheet having connection patterns connected with the base layer shown in FIG. 7A;

FIG. 8A is a plan view of a ground layer over a cavity in the ceramic package shown in FIG. 5;

FIG. 8B is a plan view of a sheet having connection patterns connected with the ground layer shown in FIG. 8A;

FIG. 9 is a perspective view of ceramic sheets of a high frequency module having a ceramic package structure of the invention; and

FIG. 10 is a sectional view of an alternative to the ceramic package shown in FIG. 5.

### DETAILED DESCRIPTION OF THE PREFERRED EMBODIMENT

The following detailed description will present preferred embodiments of the invention in reference to the accompanying drawings.

Package Structure

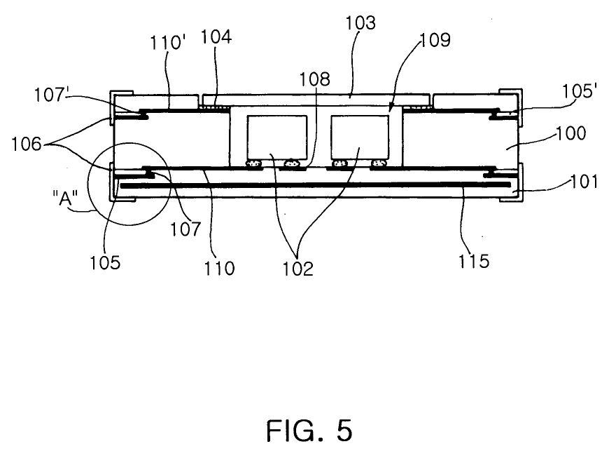

FIG. 5 is a sectional view of a ceramic package of the invention. The ceramic package in FIG. 5 comprises a layered structure made of a plurality of ceramic sheets stacked one atop another, a cover or lid mounted on the top of the layered structure, outside connection terminals formed in outer portions of the layered structure and inside connection terminals connected to a cavity of the layered structure.

The layered structure 100 and 101 in the ceramic package of the invention includes a plurality of material sheets stacked one atop another to form a single package, in which material sheets showing electrical, dielectric and magnetic properties are properly selected. In particular, each of the material sheets typically makes use of a ceramic green sheet of a predetermined thickness, and a metal coat is applied on the each material sheet in a predetermined configuration to form a pattern layer. A plurality of pattern layers of this type are stacked one atop another to perform functions of several circuit elements. The pattern layers are made of metal such as silver (Ag) and copper (Cu). Several ceramic sheets of the above type are stacked one atop another and then co-fired at a temperature under a melting point of metal to obtain a layered structure which is referred to as a Low Temperature Co-fired Ceramic (LTCC) substrate.

The layered structure includes a base layer 101 on which components 102 are mounted and an intermediate or cavity layer 100 which overlies the base layer 101, forming a cavity 109 therein. In general, the cavity 109 is formed in a central portion of the layered structure to provide a space, that is, the cavity 109 in which the components are housed. Some of the components housed in the cavity 109 require airtightness to the cavity 109. A lid 103 is mounted over the cavity 109 via bonding means in order to maintain airtightness.

In the meantime, internal patterns 115 are formed in some or entire portions of the base layer 101 and the cavity layer 100 of the layered structure to function as circuit elements.

Further, examples of the components housed within the airtight cavity include a Surface Acoustic Wave (SAW) filter, a Power Amplifier Module (PAM) containing active elements such as a transistor. Since these components tend to severely change their properties according to external environments such as moisture, temperature and dust, the cavity for housing the components is required to keep airtight in order to protect the components from the external environments.

Outside connection terminals 106 are formed in outer portions of the layered structure for signal interchange with the outside. The outside terminals 106 may be formed in any regions of the layered structure according to design requirements, but are generally formed in lateral portions of the multilayer ceramic sheets as articles are miniaturized and pattern design is sophisticated. Also with the invention, the outside terminals of the ceramic package are connected with the internal patterns in lateral portions of the package to enable signal interchange.

The components 102 housed in the cavity 109 of the layered structure are electrically connected with the inside connection terminals 108, which are also electrically connected with the outside connection terminals to enable signal interchange between the components 102 and the outside.

Lower internal connection patterns 105, 107 and 110 are formed between the base and cavity layers 100 and 101 to connect the inside connection terminals 108 with the outside connection terminals 106. The lower internal connection patterns 105, 107 and 110 are formed, separately, on different layers of the stacked ceramic sheets.

Internal Connection Pattern

FIG. 5 illustrates the lower internal connection patterns 105, 107 and 110 formed in the base layer 101 together with upper internal connection patterns 105′, 107′ and 110′ formed in top portions of the cavity layer 100. The lower internal connection patterns 105, 107 and 110 in the base layer 101 will be described first.

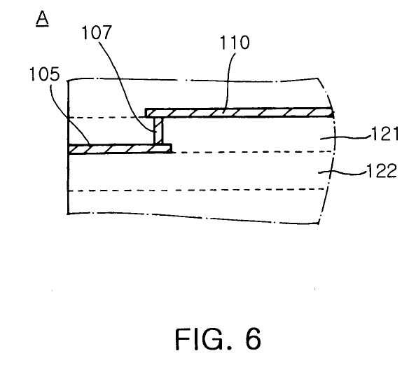

FIG. 6 is a magnification of a part A in FIG. 5. In the ceramic package of the invention, the lower internal connection patterns 105, 107 and 110 for connecting the inside connection terminals 108 with the outside connection terminals 106 are divided across at least two of the ceramic sheets as shown in FIG. 6.

The internal connection patterns may include the upper internal connection patterns 105′, 107′ and 110′ formed adjacent to the lid 103 and the lower internal connection patterns 105, 107 and 110 leading to the inside connection terminals 108. The upper internal connection patterns 105′, 107′ and 110′ are in contact with the underside of the lid 103 via the bonding means 104. The upper internal connection patterns are adapted to mainly perform a grounding function, without being connected with inside connection terminals 108.

Further, the lower internal connection patterns 105, 107 and 110 serve to electrically connect the inside connection terminals 108, which are in contact with the components 102 housed inside the cavity 109, with the outside connection terminals. In particular, the first pattern 110 is formed horizontally on a first ceramic sheet 121, the second pattern 105 is formed horizontally on a second ceramic sheet 122 to be electrically connected with the first pattern 110 through via holes 107.

The via holes 107 are filled with conductive material and perforated through the ceramic sheet 121 where the first pattern 110 is formed, in which the first ceramic sheet 121 and the second ceramic sheet 122 are formed adjacent to each other. It is to be understood that the internal connection patterns are described for illustrative purposes only, but scope of the invention is not limited thereto. That is, the internal connection terminals may be separately formed in three or more ceramic sheets.

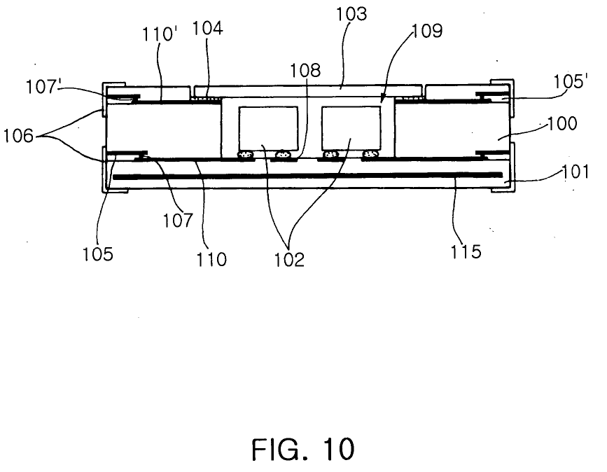

The first pattern 110 may be positioned above the second pattern 105 as shown in FIG. 5. Alternatively, as shown in FIG. 10, a first pattern 110 may be positioned under a second pattern 105. In internal connection patterns of FIG. 10, via holes 107 are perforated through a ceramic sheet 122 where the second pattern 105 is formed.

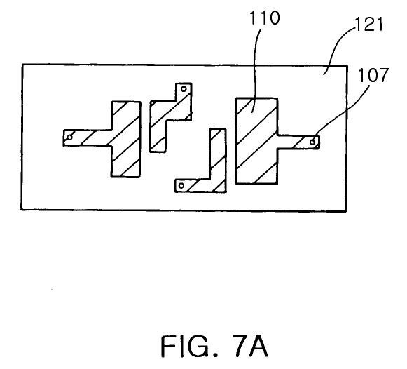

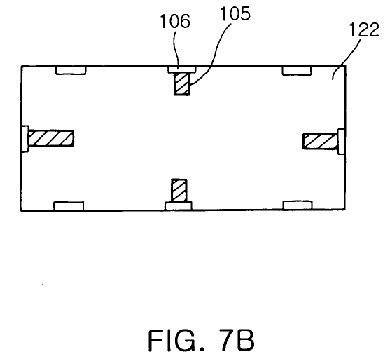

FIG. 7A is a plan view illustrating the uppermost ceramic sheet 121 of the base layer 101 of the ceramic package in FIG. 5. In FIG. 7A, the first pattern 110 of the internal connection patterns is not extended to the outer periphery where the outside terminals are located, but to a position spaced apart from the outer periphery by a predetermined gap. The cavity layer 100 and the base layer 101 commonly made of ceramic are co-fired in direct contact with each other via the gap to form a completely closed cavity. The conductive via holes 107 are formed at ends of the first pattern 110, and serves to electrically connect the first pattern 110 with the second pattern 105 shown in FIG. 7B.

In the prior art, since the conventional internal connection patterns were formed on a single ceramic sheet and extended to the outer periphery of the substrate, leaks occur on the surface of the sheet on which the internal connection patterns are formed, in process of stacking the ceramic sheets one atop another. The structure of this invention functions to prevent the above problem.

The second pattern 105 shown in FIG. 7B is connected with the first pattern 110 in FIG. 7A. The second pattern 105 is connected with the outside connection terminals 106, and extended inward to predetermined lengths. The second pattern 105 is connected with the first pattern 110 through the via holes 107 which are formed in the first pattern 110. As a result, the second pattern 105 connects the inside connection terminals with the outside connection terminals 106.

The leak paths of the prior art can be substantially removed by forming the second pattern as shown in FIG. 7B. The second pattern in ceramic sheet 122 comprises internal patterns 105, which are formed between the ceramic sheets at small lengths to shorten the leak paths thereby preventing leak. Second patterns 105 are not extended into the cavity to advantageously prevent leak generation from inside the ceramic sheet.

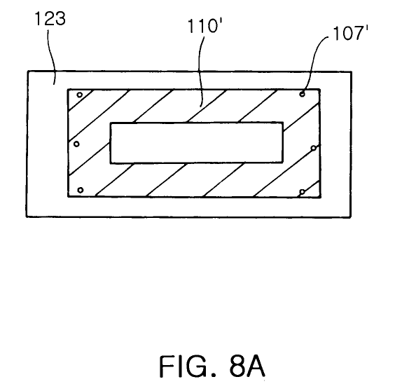

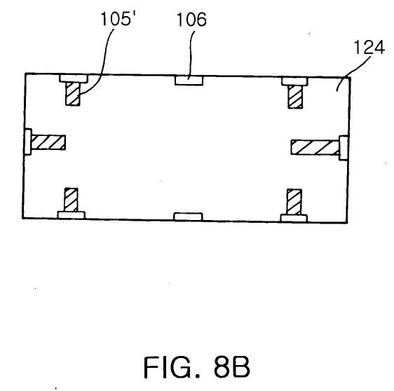

FIG. 8A is a plan view illustrating a ground layer above the cavity in the ceramic package shown in FIG. 5. In FIG. 8A, a first pattern 110′ is formed on a first ceramic sheet 123 of the ground layer above the cavity. The first pattern 110′ is not connected with the outside connection terminals but formed only within the ceramic sheet 123, as the internal connection patterns in the base layer are not.

FIG. 8B illustrates a second ceramic sheet 124 underlying the first ceramic sheet 123, in which the second pattern 105′ formed in the second ceramic sheet 124 is connected with the first pattern 110′. The second pattern 105′ is connected with the outside connection terminals 106, and extended inward up to positions to contact the via holes 107′ of the first pattern 110′.

The upper internal connection patterns are also separately formed in two ceramic sheets so that the package is substantially free of leak paths from inside or outside.

As shown in the above drawings, the internal connection patterns are extended horizontally toward the lateral portions of the ceramic package, divided through at least two sheets, thereby preventing leak paths. The connection patterns are not formed in the underside of the ceramic package to prevent reduction of the internal circuit pattern design area of the ceramic package formed by stacking a number of ceramic sheets one atop another, thereby improving design flexibility of circuit pattern. These characteristics will be described later in detail.

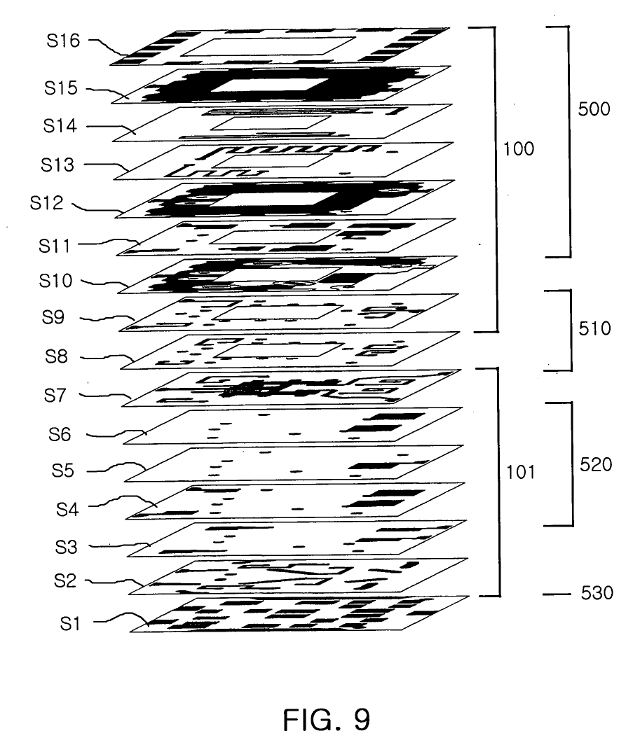

FIG. 9 illustrates the structure of dielectric sheets which constitute a dielectric layered structure for forming a high frequency module as an exemplary ceramic package of the invention. In FIG. 9, first through seventh dielectric sheets S1 through S7 form the base layer 101 functioning as a lower layered structure, and eighth through sixteenth dielectric sheets S8 through S16 form the upper cavity layer 100 on which the components are mounted.

The high frequency module shown in FIG. 9 has a combined structure of a diplexer and an SAW duplexer, in which the diplexer functions to distribute signals received via an antenna to a first or second communication system as well as transfer signals from the first or second communication system to the antenna. In the meantime, the SAW duplexer transfers a signal from the diplexer to a receiving block of the first communication system and sends a signal from a transmitting block of the first communication system to the diplexer.

In order to embody both the diplexer and the SAW duplexer in one package, a plurality of circuit elements are formed in a multilayer substrate. Referring to FIG. 9, a capacitor pattern layer 510 is formed through the third to sixth dielectric sheets S6, an inductor pattern layer 520 is formed through the seventh to ninth dielectric sheets S9. A ground and inductance pattern layer 500 is formed through the tenth to sixteenth dielectric sheets S10 to S16, and the lowermost sheet S1 forms an attachment layer 530 to which attached are a plurality of devices such as a diode, MLCC and resistor.

As described above, according to a current tendency, the art is gradually commercializing composite modules provided in one ceramic package to perform multifunction. The composite modules perform several functions such as a duplexer and diplexer. In order to realize these functions through patterning, it is necessary to form several circuit patterns not only in the cavity layer 100 but also in the base layer 101 in the package at a gradually increasing degree of integration. As a result, it is becoming impossible to form via holes vertically all the way down to the bottom of the package without influence on the design of patterns for realizing the circuit elements in the package.

Therefore, as set forth above, the ceramic package of the invention can be applied to any package structure having the internal circuit patterns for embodying the several circuit elements in the ceramic sheet underlying the lower internal connection patterns. Such a ceramic package improves design flexibility by preventing the reduction of the area for forming internal circuit patterns, because connection patterns are not formed vertically all the way down to the bottom of the package.

Fabrication Process

A ceramic package of the invention fabrication process is carried out according to following steps:

a) Preparing a plurality of ceramic sheets:

In the ceramic package of the invention, ceramic sheets for forming a layered structure are ceramic green sheets of predetermined thicknesses, and each of the ceramic sheets is covered with a metal coat thereon in a predetermined configuration to form a pattern layer. Pattern layers of this type are stacked on the ceramic sheets to function as several circuit elements. The pattern layers are made of metal such as Ag and Cu.

The ceramic sheets used in the ceramic package of the invention are so prepared that stacking the ceramic sheets forms a cavity for housing several types of components.

b) Forming pattern layers to obtain circuit elements on at least a portion of the ceramic sheets:

A pattern layer is formed on at least a portion of the ceramic sheets to obtain the circuit elements. The pattern layer constitutes passive elements (R, L, C) and so one for embodying a given circuit, and is designated with the reference number 115 in FIG. 5. LTCC technology, which forms pattern layers in a number of ceramic sheets to obtain circuit elements through combination of the pattern layers, has process characteristics of enabling co-firing of ceramic and metal to advantageously form passive elements in a module, thereby reducing the size and thickness of composite components.

Further, the pattern layers can be realized respectively in at least a portion of the ceramic layers according to design requirements of the ceramic package.

c) Forming outside connection terminals for signal interchange with the outside and forming_inside connection terminals connected with the components in a portion of the ceramic sheets:

On a portion of the ceramic sheets, in particular, the uppermost surface of the base layer 101 shown in FIG. 5, there are formed the inside connection terminals 108 to be connected with the outside connection terminals 106 formed in outer portions of the substrate and the components housed therein.

d) Separately forming the internal connection patterns on at least two ceramic sheets for connecting the outide connection terminals or a lid mounted above the cavity with the inside connection terminals:

After the above process step, the internal connection patterns are formed to electrically connect the inside connection terminals with the outside connection terminals or the lid with the outside connection terminals. In this case, the internal connection patterns are separately formed on at least two ceramic sheets instead of being formed continuously on one ceramic sheet as in the prior art. Such separate formation can be seen from FIGS. 5 through 8B and FIG. 10.

The internal connection patterns for connecting the inside connection terminals 108 with the outside connection terminals 106 are formed horizontally for example across two of the ceramic sheets as shown in FIG. 6. That is, the first pattern 110 is formed horizontally on the first ceramic sheet 121 to be connected with the inside connection terminals and the second pattern 105 is formed horizontally on the second ceramic sheet 122 to be connected with the first pattern 110.

As separately formed between at least two of the ceramic sheets, the internal connection patterns advantageously avoid formation of leak paths. Also, the connection patterns are not formed in the underside of the ceramic package to prevent reduction of the internal pattern design area of the ceramic package which is realized by stacking the ceramic sheets one atop another, thereby improving the flexibility of design.

e) Forming the conductive via holes in at least a portion of the ceramic sheets to electrically connect the separate internal connection patterns:

The first pattern 110 and the second pattern 105 are electrically connected through the via holes 107. Referring to FIG. 6, the via holes are formed in upper one of the two ceramic sheets having the internal connection patterns. The via holes function to electrically connect the separate internal connection patterns.

f) Stacking the ceramic sheets:

The ceramic sheets after the above steps are pressed to a predetermined pressure to form a ceramic package. Since the above structure avoids formation of leak paths within the package unlike the prior art, there is an advantage that an excessive amount of stacking pressure is not necessary.

As set forth above, the present invention prevents formation of the leak paths along which leak occurs from outside so that the ceramic package does not have any leak defects. The ceramic package of the invention also can maintain an improved level of airtightness.

Furthermore, the invention can prevent defective mounting of components resulting from degraded evenness of a bottom for mounting the components which may be caused by excessive pressing ceramic sheets for the purpose of preventing leak defects in fabrication of a ceramic package.

Moreover, the invention can improve the design flexibility of patterns for forming circuit elements of ceramic multilayer sheets as well as reduce the size of an article.

While the present invention has been described with reference to the particular illustrative embodiments, it is to be appreciated that those skilled in the art can change or modify the embodiments without departing from the scope and spirit of the present invention, which will be defined by the appended claims.

What is claimed is:

1. A ceramic package for internally mounting at least one component, comprising:
a layered structure formed by stacking a plurality of ceramic sheets one atop another, having an internal cavity for housing the component and internal patterns in at least a portion of the ceramic sheets;
a lid mounted on the layered structure above the cavity to maintain the cavity airtight;
outside connection terminals formed on outer portions of the layered structure;
internal connection patterns separately formed horizontally in at least two of the ceramic sheets to be electrically connected with the outside connection terminals; and
inside connection terminals formed within the cavity to be electrically connected with the component and at least a portion of the internal connection patterns.

2. The ceramic package as set forth in claim 1, wherein the separate internal connection patterns are electrically connected through via holes.

3. The ceramic package as set forth in claim 1, wherein the internal connection patterns are separately formed in adjacent ones of the ceramic sheets.

4. The ceramic package as set forth in claim 1, wherein the internal connection patterns comprise upper internal connection patterns formed adjacent to the lid and lower internal connection patterns connected with the inside connection terminals.

5. The ceramic package as set forth in claim 4, wherein the lower internal connection patterns comprise a first pattern which is formed on a ceramic sheet as that of the inside connection terminals for electric connection therewith, and a second pattern which is connected with the outside connection terminals and formed in a second ceramic sheet different from that of the first pattern.

6. The ceramic package as set forth in claim 4, wherein the upper internal connection patterns comprise a first pattern formed on a layer on which the lid is mounted, and a second pattern which is connected with the outside connection terminals and formed on a ceramic sheets different from that of the first pattern.

7. The ceramic package as set forth in claim 4, further comprising inside patterns for realizing circuit elements in at least one of the ceramic sheets which underlies the lower internal connection patterns.

8. A fabrication method of a ceramic package capable of mounting components within a cavity, the method comprising the steps of:
preparing a plurality of ceramic sheets;
forming pattern layers in at least a portion of the ceramic sheets to realize circuit elements;
forming outside connection terminals for signal interchange with the outside and forming inside connection terminals connected with the components in a portion of the ceramic sheets;
separately forming internal connection patterns on at least two of the ceramic sheets, for connecting the outside connection terminals with the lid mounted over the cavity or with the inside connection terminals;
forming conductive via holes in a portion of the ceramic sheets to electrically connect the separate internal connection patterns which are formed in the ceramic sheets; and
stacking the ceramic sheets one atop another.

9. The fabrication method as set forth in claim 8, wherein the internal connection patterns are separately formed in adjacent ones of the ceramic sheets.

10. The fabrication method as set forth in claim 8, wherein the internal connection patterns comprise upper internal connection patterns formed adjacent to the lid and second internal connection patterns connected with the inside connection terminals.

11. The fabrication method as set forth in claim 10, wherein the lower internal connection patterns comprise a first pattern which is formed on a same ceramic sheet as that of the inside connection terminals for electric connection therewith, and a second pattern which is connected with the outside connection terminals and formed in a second ceramic sheet different from that of the first pattern.

12. The fabrication method as set forth in claim 10, wherein the upper internal connection patterns comprise a first pattern formed on a layer on which the lid is mounted, and a second pattern which is connected with the outside connection terminals and formed on a ceramic sheet different from that of the first pattern.

13. The fabrication method as set forth in claim 10, wherein inside patterns for realizing circuit elements are provided in at least one of the ceramic sheets which underlies the lower internal connection patterns.
